(19) United States
(12) Patent Application Publication
(10) Pub. No.: US 2025/0357095 A1
(43) Pub. Date: Nov. 20, 2025

(54) METHOD FOR CONTROLLING PLASMA MEASUREMENT SYSTEM AND PLASMA MEASUREMENT SYSTEM

(71) Applicant: Tokyo Electron Limited, Tokyo (JP)

(72) Inventors: Eiki KAMATA, Yamanashi (JP); Mitsutoshi ASHIDA, Yamanashi (JP); Nobuhiko YAMAMOTO, Osaka (JP)

(21) Appl. No.: 19/195,653

(22) Filed: Apr. 30, 2025

(30) Foreign Application Priority Data
May 14, 2024 (JP) 2024-078915

(51) Int. Cl. H01J 37/32

(52) U.S. Cl. CPC H01J 37/32935

(57) ABSTRACT

Provided is a method for controlling a plasma measurement system including a probe device of a plasma processing apparatus, and a measurement circuit that outputs an AC voltage for plasma measurement to the probe device and measures a state of plasma generated by the plasma processing apparatus, wherein an absolute value of a voltage applied to the probe device during cleaning of the plasma processing apparatus is greater than an absolute value of the AC voltage for the plasma measurement.

### CROSS-REFERENCE TO RELATED APPLICATIONS

This application claims priority to Japanese Patent Application No. 2024-078915 filed on May 14, 2024, the entire contents of which are incorporated herein by reference.

### TECHNICAL FIELD

The present disclosure relates to a method for controlling a plasma measurement system and a plasma measurement system.

### BACKGROUND

Japanese Laid-open Patent Publication No. 2019-46787 discloses a plasma probe device including an antenna part attached to an opening formed in a wall of a processing chamber or in a placing table via a sealing member that seals a gap between a vacuum space and an atmospheric space, an electrode connected to the antenna part, and a dielectric support part made of a dielectric and configured to support the antenna part from the periphery thereof. The antenna part and the facing surface of the wall or the placing table are separated by a predetermined width, and the surface of the antenna part exposed from the opening is recessed from the surface of the wall or the placing table on the plasma generation space side where the opening is formed.

### SUMMARY

In one aspect, the present disclosure provides a control method for a plasma measurement system and a plasma measurement system that desirably cleans a probe device.

In accordance with an aspect of the present disclosure, there is provided a method for controlling a plasma measurement system including a probe device of a plasma processing apparatus, and a measurement circuit that outputs an AC voltage for plasma measurement to the probe device and measures a state of plasma generated by the plasma processing apparatus, wherein an absolute value of a voltage applied to the probe device during cleaning of the plasma processing apparatus is greater than an absolute value of the AC voltage for the plasma measurement.

### BRIEF DESCRIPTION OF THE DRAWINGS

FIG. 1 is a schematic cross-sectional view showing an example of a plasma processing apparatus according to an embodiment.

FIG. 2 is a diagram showing an example of the II-II cross section of FIG. 1.

FIG. 3 is a diagram showing an example of the functional configuration of a measurement system and a controller according to an embodiment.

FIG. 4 is a flowchart showing an example of a method for controlling a plasma processing apparatus.

FIGS. 5A and 5B show examples of a circuit model of the measurement system.

FIGS. 6A and 6B show examples of a graph showing an estimated plasma electron temperature.

FIG. 7 shows an example of a diagram schematically showing the supply of a processing gas, the supply of a cleaning gas, a voltage supplied to a probe device, and changes in a film thickness in a first substrate processing method.

FIGS. 8A to 8C show examples of a diagram showing a circuit configuration for applying a voltage to the probe device.

FIG. 9 shows another example of a diagram showing a circuit configuration for applying a voltage to the probe device.

FIGS. 10A and 10B are diagrams showing an example of a voltage applied to the probe device.

FIG. 11 shows an example of a diagram schematically showing the supply of a processing gas, the supply of a cleaning gas, a voltage supplied to the probe device, and changes in a film thickness in a second substrate processing method.

FIG. 12 is an example of a diagram schematically showing the supply of a processing gas, the supply of a cleaning gas, a voltage supplied to the probe device, and changes in a film thickness in a third substrate processing method.

FIG. 13 is an example of a diagram schematically showing the supply of a processing gas, the supply of a cleaning gas, a voltage supplied to the probe device, and changes in a film thickness in a fourth substrate processing method.

FIG. 14 is another example of a diagram showing a circuit configuration for applying a voltage to the probe device.

### DETAILED DESCRIPTION

Hereinafter, embodiments of the present disclosure will be described in detail with reference to the accompanying drawings. Like reference numerals will be used for like or corresponding parts throughout the drawings, and redundant description thereof may be omitted.

### (Plasma Processing Apparatus)

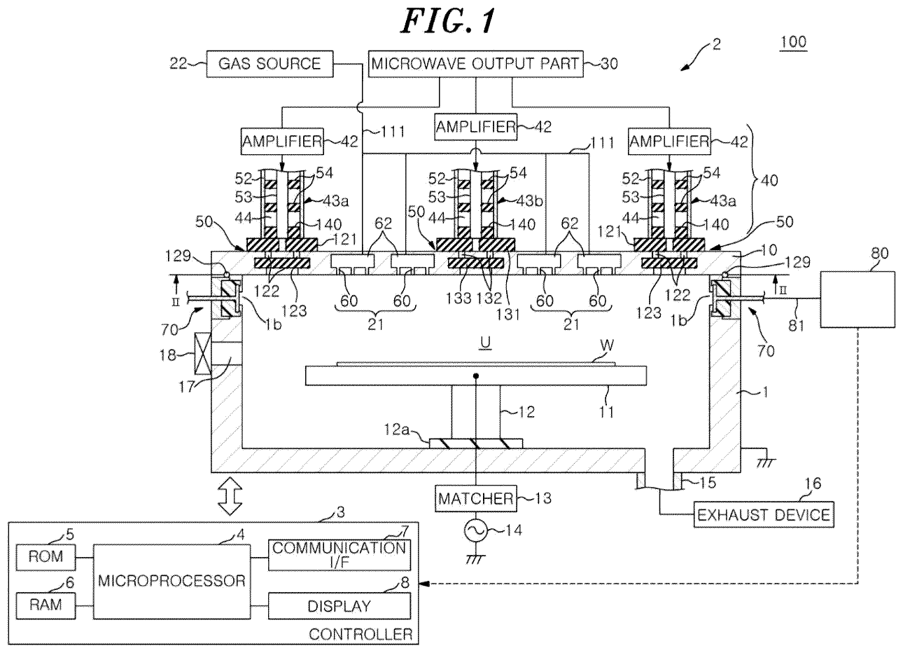

FIG. 1 shows an example of a cross-sectional view of a plasma processing apparatus 100 according to one embodiment of the present disclosure. The plasma processing apparatus 100 includes a processing chamber 1 that accommodates a substrate W that is an example of a semiconductor wafer. The plasma processing apparatus 100 is an example of a plasma processing apparatus that performs plasma processing on the substrate W by using surface wave plasma generated at a bottom surface of a ceiling wall 10 of the processing chamber 1 by microwaves. The plasma processing includes film formation, etching, and ashing using plasma.

The plasma processing apparatus 100 includes the processing chamber 1, a microwave plasma source 2, and a controller 3. The processing chamber 1 is an airtight substantially cylindrical chamber made of a metal material such as aluminum or stainless steel. The processing chamber 1 is grounded.

The processing chamber 1 has the ceiling wall 10, and forms therein a space (plasma generation space U) for performing plasma processing on the substrate W. The ceiling wall 10 is a lid that is formed in a disc shape and closes the upper opening of the processing chamber 1. A support ring 129 is provided on the contact surface between the processing chamber 1 and the ceiling wall 10, thereby hermetically sealing the inside of the processing chamber 1. The ceiling wall 10 is made of a metal material such as aluminum or stainless steel.

The microwave plasma source 2 has a microwave output part 30, a microwave transmission part 40, and a microwave radiation mechanism 50. The microwave output part 30 outputs microwaves by distributing them to a plurality of paths. The microwaves are introduced into the processing chamber 1 through the microwave transmission part 40 and the microwave radiation mechanism 50. A gas supplied into the processing chamber 1 is excited by the electric field of the introduced microwaves, thereby generating surface wave plasma.

A placing table 11 for placing a substrate W is provided in the processing chamber 1. The placing table 11 is supported by a cylindrical support member 12 standing upright at the center of the bottom portion of the processing chamber 1 via an insulating member 12a. The materials forming the placing table 11 and the support member 12 include a metal such as aluminum having an alumite-treated (anodically oxidized) surface or an insulating member (ceramic or the like) having therein a high-frequency electrode. The placing table 11 may be provided with an electrostatic chuck for electrostatically attracting the substrate W, a temperature control mechanism, a gas channel for supplying a heat transfer gas to the backside of the substrate W, or the like.

A high-frequency bias power supply 14 is connected to the placing table 11 via a matcher 13. When a high-frequency power is supplied from the high-frequency bias power supply 14 to the placing table 11, ions in the plasma are attracted toward the substrate W. Further, the high-frequency bias power supply 14 may not be provided depending on the characteristics of the plasma processing.

An exhaust line 15 is connected to the bottom portion of the processing chamber 1, and an exhaust device 16 including a vacuum pump is connected to the exhaust line 15. When the exhaust device 16 operates, the inside of the processing chamber 1 is exhausted and, thus, a pressure in the processing chamber 1 is quickly depressurized to a predetermined vacuum level. A loading/unloading port 17 for loading/unloading the substrate W and a gate valve 18 for opening/closing the loading/unloading port 17 are provided on the sidewall of the processing chamber 1.

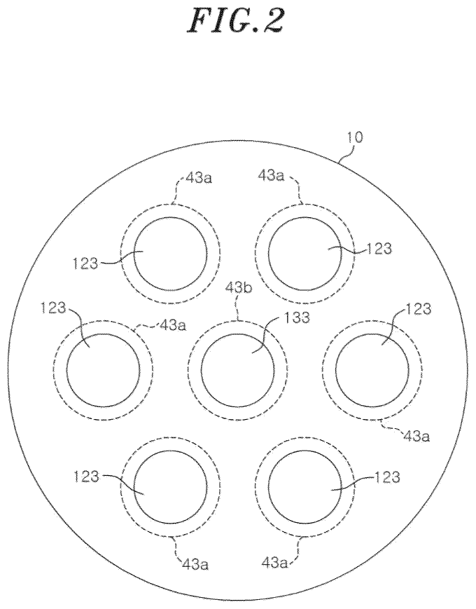

The microwave transmission part 40 transmits microwaves outputted from the microwave output part 30. FIG. 2 shows a cross section taken along line II-II in FIG. 1, and illustrates an example of the bottom surface of the ceiling wall of the plasma processing apparatus 100. Referring to FIG. 2, a central microwave introducing part 43b in the microwave transmission part 40 is located at the center of the ceiling wall 10, and six peripheral microwave introducing parts 43a are located at equal intervals in the circumferential direction at the periphery of the ceiling wall 10. The central microwave introducing part 43b and the six peripheral microwave introducing parts 43a have the function of introducing the microwaves outputted from corresponding amplifier 42 shown in FIG. 1 to the microwave radiation mechanism 50 and the function of matching an impedance. Hereinafter, the peripheral microwave introducing parts 43a and the central microwave introducing part 43b are collectively referred to as the microwave introducing part 43.

As shown in FIGS. 1 and 2, six dielectric windows 123 on the outer peripheral side are located inside the ceiling wall 10 under the six peripheral microwave introducing parts 43a. Further, the central dielectric window 133 is located inside the ceiling wall 10 under the central microwave introducing part 43b. Further, the number of the peripheral microwave introducing parts 43a and the number of the dielectric windows 123 are not limited to six, and may be two or more. However, the number of the peripheral microwave introducing parts 43a is preferably three or more, and may be, for example, three to six.

The microwave radiation mechanism 50 shown in FIG. 1 includes wave retardation plates 121 and 131, slots 122 and 132, and dielectric windows 123 and 133. The wave retardation plates 121 and 131 are made of a disc-shaped dielectric material that transmits microwaves, and are located on the upper surface of the ceiling wall 10. The wave retardation plates 121 and 131 are made of ceramic such as quartz or alumina (Al₂O₃), fluorine-based resin such as polytetrafluoroethylene, or polyimide-based resin, which have a relative dielectric constant greater than that of vacuum. Accordingly, the wave retardation plates 121 and 131 have a function of reducing a size of the antenna including the slots 122 and 132 by making the wavelength of the microwaves transmitted through the wave retardation members 121 and 131 shorter than the wavelength of the microwaves propagating in vacuum.

Under the wave retardation plates 121 and 131, the dielectric windows 123 and 133 are in contact with the back surface of the opening in the ceiling wall 10 via the slots 122 and 132 formed in the ceiling wall 10. The dielectric windows 123 and 133 are made of, for example, ceramic such as quartz or alumina (Al₂O₃), fluorine-based resin such as polytetrafluoroethylene, or polyimide-based resin. The dielectric windows 123 and 133 are located at positions recessed from the ceiling surface by the thickness of the opening formed in the ceiling wall 10, and are configured to supply microwaves to the plasma generation space U.

In the peripheral microwave introducing part 43a and the central microwave introducing part 43b, a cylindrical outer conductor 52 and a rod-shaped inner conductor 53 provided at the center of the cylindrical outer conductor 52 are coaxially arranged. A microwave power is supplied to the gap between the outer conductor 52 and the inner conductor 53, and the gap therebetween serves as a microwave transmission path 44 through which microwaves propagate toward the microwave radiation mechanism 50.

Each of the peripheral microwave introducing part 43a and the central microwave introducing part 43b is provided with a slug 54 and an impedance adjusting member 140 located at the tip end of the slug 54. The impedance adjusting member 140 has a function of matching an impedance of a load (plasma) in the processing chamber 1 with a characteristic impedance of a microwave power source in the microwave output part 30 by moving the slug 54. The impedance adjusting member 140 is made of a dielectric material, and is configured to adjust the impedance of the microwave transmission path 44 based on its relative dielectric constant.

The ceiling wall 10 is provided with a gas introducing part 21 having a shower structure. A gas supplied from a gas supply source 22 reaches the gas diffusion space 62 through a gas supply line 111, and is supplied into the processing chamber 1 in a shower pattern through the gas introducing part 21. The gas introducing part 21 is an example of a gas shower head for supplying a gas from a plurality of gas supply holes 60 formed in the ceiling wall 10. The gas may be a gas for plasma generation, such as Ar gas, a gas to be decomposed with high energy, such as O₂ gas or N₂ gas, a processing gas such as silane gas, or the like.

Individual components of the plasma processing apparatus 100 are controlled by the controller 3. The controller 3 includes a microprocessor 4, a read only memory (ROM) 5, and a random access memory (RAM) 6. A process sequence of the plasma processing apparatus 100 and a process recipe that is a control parameter are stored in the ROM 5 or the RAM 6. The microprocessor 4 controls the individual components of the plasma processing apparatus 100 based on the process sequence and the process recipe. Further, the controller 3 has a communication interface (I/F) 7, and can communicate with other devices. Further, the controller 3 has a display 8, and can display results at the time of performing predetermined control based on the process sequence and the process recipe.

In the case of performing plasma processing in the plasma processing apparatus 100 configured as described above, first, the substrate W is held on a transfer arm (not shown) and loaded into the processing chamber 1 from the open gate valve 18 through the loading/unloading port 17. When the substrate W is transferred to a position above the placing table 11, the substrate W is transferred from the transfer arm to a pusher pin and is placed on the placing table 11 by lowering the pusher pin. The gate valve 18 is closed after the substrate W is loaded. The pressure in the processing chamber 1 is maintained at a predetermined vacuum level by the exhaust device 16. The processing gas is introduced into the processing chamber 1 from the gas introducing part 21 in a shower pattern. The microwaves emitted from the microwave radiation mechanism 50 via the microwave introducing part 43 propagate near the bottom surface that is the inner surface of the ceiling wall. The gas is excited by the electric field of the surface-wave microwave, and the substrate W is subjected to plasma processing by the surface wave plasma generated in the plasma generation space U under the ceiling wall in the processing chamber 1.

### (Probe Device)

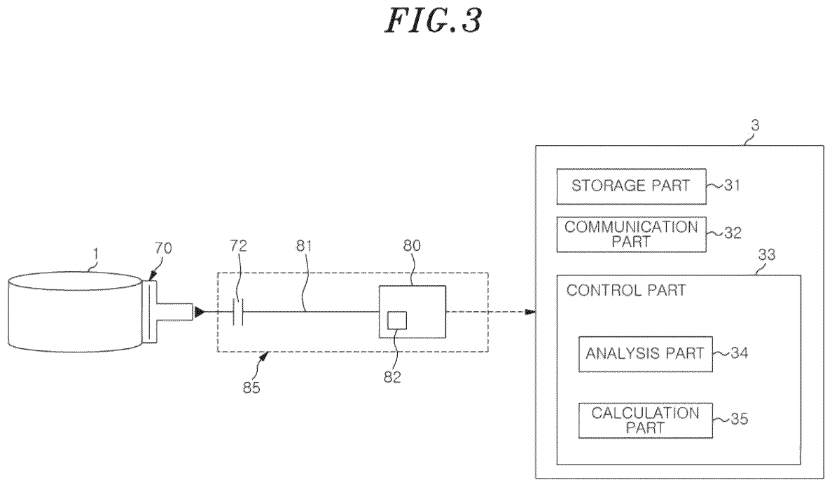

The description of the probe device 70 will be continued with reference to FIGS. 1 and 3. FIG. 3 shows an example of a functional configuration of a measurement system and a controller according to an embodiment. As shown in FIG. 1, one or multiple openings 1b are formed in the sidewall of the processing chamber 1 in the circumferential direction, and one or multiple probe devices 70 are installed via a sealing member (not shown) for sealing the gap between a vacuum space and an atmospheric space.

A gap with a predetermined width is formed between the tip end surface of the probe device 70 and the back surface near the opening 1b formed in the wall of the processing chamber 1. The gap is designed to be wide enough to prevent the probe device 70 from being connected to the wall of the processing chamber 1 in a DC manner, and narrow enough to prevent inflow of plasma or a gas. However, the probe device 70 may be installed at the opening formed in the placing table via a sealing member.

As shown in FIG. 3, the measurement system for measuring a plasma state includes the probe device 70 and a measurement circuit 85. The measurement circuit 85 has a monitor device 80, a blocking capacitor 72, and a coaxial cable 81. The monitor device 80 is connected to the controller 3 to be able to communicate therewith.

The probe device 70 is connected to the monitor device 80 via the coaxial cable 81 outside the plasma processing apparatus 100. The monitor device 80 has a signal generator 82, and the signal generator 82 outputs an AC voltage signal of a predetermined frequency to the coaxial cable 81. The AC voltage signal is transmitted through the coaxial cable 81, and the AC voltage is applied to the probe device 70. The blocking capacitor 72 is connected to the coaxial cable 81, transmits the AC voltage signal to the probe device 70, and blocks the DC voltage signal. As a result, the monitor device 80 receives only the AC voltage signal from the plasma side.

The probe device 70 senses plasma generated in the plasma generation space U. The probe device 70 detects a current signal flowing to the plasma side from a signal transmitted to the plasma side, and transmits it to the monitor device 80. The current signal flowing to the plasma side is transmitted from the monitor device 80 to the controller 3, and is received by the communication part 32 of the controller 3. The current value of the received signal is stored in a storage part 31. An analysis part 34 of a control part 33 performs fast Fourier transform (FFT) analysis on the current value of the received signal. A calculation part 35 of the control part 33 calculates a plasma electron temperature Tₑ or a plasma electron density Nₑ, which will be described later, based on the analysis result. Hence, the plasma state can be estimated accurately.

The storage part 31 is realized by the ROM 5 or the RAM 6 shown in FIG. 1. The communication part 32 is realized by a communication interface 7. The analysis part 34 and the calculation part 35 of the controller 33 are realized by the microprocessor 4.

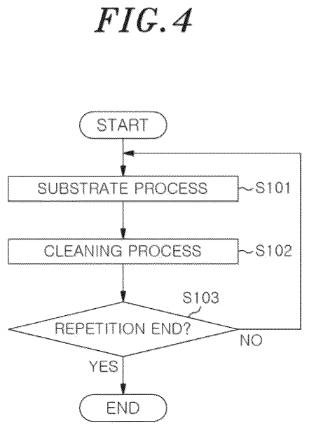

FIG. 4 is a flowchart showing an example of a method for controlling the plasma processing apparatus 100.

In step S101, the substrate processing is performed. Here, the controller 3 controls the gas supply source 22 to supply a processing gas (film forming gas, etching gas, or the like) from the gas supply holes 60 to the plasma generation space U, and controls the microwave output part 30 and the high frequency bias power supply 14 to generate plasma of the processing gas in the plasma generation space U, thereby performing desired processing (film formation, etching, or the like) on the substrate W. In this case, an AC voltage is applied from the signal generator 82 to the probe device 70, and the probe device 70 senses the plasma generated in the plasma generation space U. Then, the controller 33 calculates the plasma electron temperature Tₑ and the plasma electron density Nₑ to estimate the plasma state.

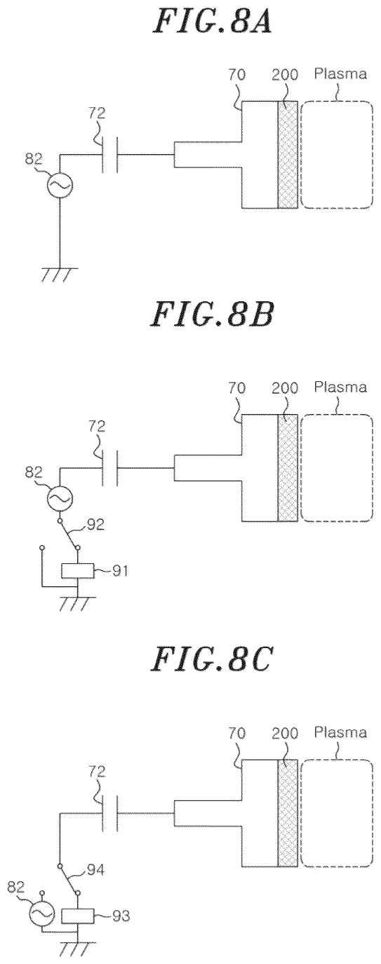

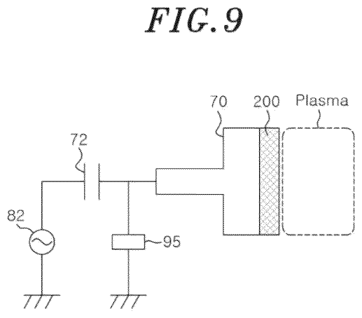

Here, if the substrate processing is a process for forming an insulating film on the substrate W, an insulator (e.g., SiN, SiO₂, or the like) is deposited on the surface (the tip end surface of the probe device 70, or the like) of the probe device 70 exposed to the plasma generation space U to form an insulating film 200 (see FIGS. 8 and 9 to be described later). The substrate processing is not limited to the formation of the insulating film, and may be processing (e.g., etching) in which an insulator is formed as reaction products, and the reaction products (insulator) are deposited on the surface exposed to the plasma generation space U of the probe device 70 to form the insulating film 200.

In step S101, the substrate processing is repeated until cleaning start conditions such as a predetermined number of processed substrates and processing time are satisfied. When the predetermined cleaning start conditions are satisfied, the processing of the controller 3 proceeds to step S102.

In step S102, a cleaning process is performed. Here, the controller 3 controls the gas supply source 22 to supply a cleaning gas (e.g., NF₃ or the like) containing fluorine (F) from the gas supply holes 60 to the plasma generation space U, and controls the microwave output part 30 and/or the high frequency bias power supply 14 to generate plasma of the cleaning gas in the plasma generation space U, thereby removing the insulating film deposited in the processing chamber 1. In addition, the insulating film 200 deposited on the surface exposed to the plasma generation space U of the probe device 70 is also removed.

Here, in the cleaning process, conductive fluoride is adhered to and accumulated on the surface of the probe device 70 exposed to the plasma generation space U. The conductive fluoride is, for example, a metal fluoride (e.g., AlF) containing a metal (e.g., Al) derived from the inner wall of the processing chamber 1 and the dielectric window 123, 133 made of alumina (Al₂O₃), and fluorine (F) derived from the cleaning gas.

In step S103, it is determined whether or not to end the repetition. If the repetition is not ended (S103, NO), the process of the controller 3 returns to step S101, and the substrate processing and the cleaning process are repeated. If the repetition is ended (S103, YES), the process of the controller 3 is ended.

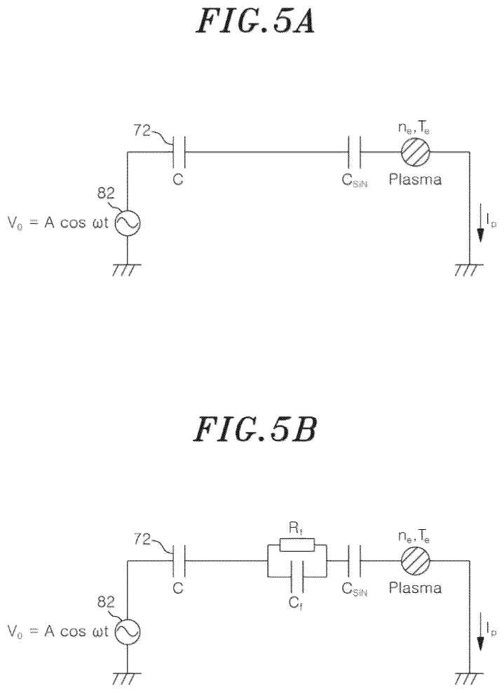

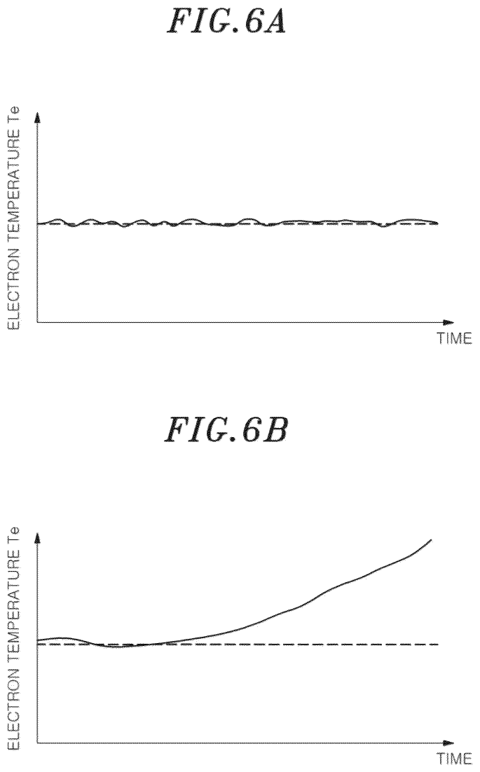

FIGS. 5A and 5B show an example of a circuit model of the measurement system. FIGS. 6A and 6B show an example of a graph showing the estimated plasma electron temperature Tₑ. FIG. 5A shows an example of a circuit model in the case where an insulating film 200 is formed on the surface of the probe device 70 exposed to the plasma generation space U. FIG. 5B shows an example of a circuit model in the case where the insulating film 200 and a conductive fluoride film are formed on the surface of the probe device 70 exposed to the plasma generation space U. FIG. 6A is a graph showing an example of changes in the estimated plasma electron temperature Tₑ over time in the case where the insulating film 200 is formed on the surface of the probe device 70 exposed to the plasma generation space U. FIG. 6B is a graph showing an example of changes in the estimated plasma electron temperature Tₑ over time in the case where the insulating film 200 and a conductive fluoride film are formed on the surface of the probe device 70 exposed to the plasma generation space U.

As shown in FIG. 5A, in a state where the insulating film 200 is formed, a capacitance component C_{SiN} exists due to the insulating film 200. The capacitance component C_{SiN} exists in series with the electrostatic capacitance C of the blocking capacitor 72. Here, the plasma is regarded as a pure resistance with a phase difference of 0° and the insulating film 200 has the capacitance component C_{SiN} with a phase difference of 90°, so that it is possible to estimate the thickness (capacitance component C_{SiN}) of the insulating film 200 and the plasma state (the plasma electron temperature Tₑ and the plasma electron density Nₑ) separately. Therefore, as shown in FIG. 6A, the estimated plasma electron temperature Tₑ indicated by the solid line is accurately estimated with respect to the actual value of the plasma electron temperature Tₑ (indicated by the dashed line).

As shown in FIG. 5B, in a state where the conductive fluoride film and the insulating film 200 are formed, a resistance component R_{f} due to the conductive fluoride film, a capacitance component C_{f} of the conductive fluoride film, and a capacitance component C_{SiN} due to the insulating film 200 exist.

Further, when the resistance component R_{f} is close to 0Ω (i.e., a conductor), the presence of the capacitance component C_{f} can be ignored and it can be treated as a conductor, and the plasma state can be estimated by calculation as in FIG. 5A on the assumption that the capacitance component C_{SiN} is in series with the capacitance C of the blocking capacitor 72. Further, when the resistance component R_{f} is close to ∞Ω, the presence of the resistance component R_{f} can be ignored and only the capacitance component C_{f} can be considered. The plasma state can be estimated by calculation in FIG. 5A on the assumption that the capacitance component C_{SiN} and the capacitance component C_{f} are in series with the capacitance C of the blocking capacitor 72.

On the other hand, when a conductive fluoride film is formed and the fluoride film has finite conductivity (in other words, when the resistance component R_{f} has a value within a range between a value that is not small enough to be considered as 0Ω and a value that is not large enough to be considered as ∞Ω), it is not possible to desirably estimate the plasma electron temperature Tₑ by the calculation process used in FIG. 5A. In other words, if the fluoride film contains the finite resistance component R_{f}, the resistance component R_{f} is added to the resistance component of the plasma, which makes it impossible to determine whether the changes in current at the time of measuring the plasma is due to the plasma or the fluoride film. Therefore, as shown in FIG. 6B, the estimated plasma electron temperature Tₑ indicated by the solid line may be far from the actual value of the plasma electron temperature Tₑ (indicated by the dashed line) as time elapses and the conductive fluoride film is accumulated, so that the estimation accuracy may deteriorate. In particular, when the conductive fluoride film is AlF, the impedance of the resistance component R_{f} and the impedance of the capacitance component C_{f} are similar and, thus, the estimation error becomes large.

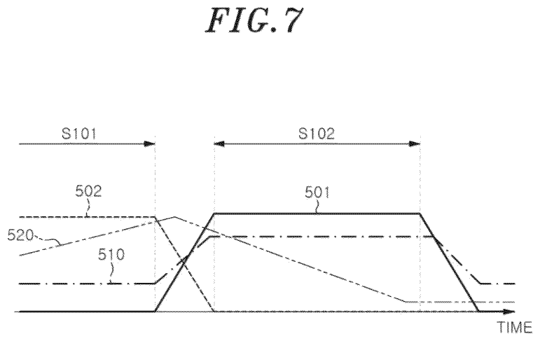

FIG. 7 is an example of a diagram schematically showing the supply of a processing gas, the supply of a cleaning gas, a voltage supplied to the probe device 70, and changes in a film thickness in a first substrate processing method. Here, a processing gas supply 502 used in step S101 is indicated by a dashed line, a cleaning gas supply 501 used in step S102 is indicated by a solid line, a voltage 510 supplied to the probe device 70 is indicated by a dashed dotted line, and a film thickness 520 of the insulating film 200 of the probe device 70 is indicated by a dashed double-dotted line.

As shown in FIG. 7, the absolute value of the voltage V_{clean} applied to the probe device 70 during the cleaning process S102 is greater than the absolute value of the AC voltage Vₚₗₐₛₘₐ for measurement that is applied to the probe device 70 at the time of measuring the plasma state (during the substrate processing in S101) (|V_{clean}|>|Vₚₗₐₛₘₐ|). As a result, during the cleaning process S102, electrons and/or ions are attracted to the surface of the probe device 70 exposed to the plasma generation space U (such as the tip end surface of the probe device 70 or the like), and the adhered conductive fluoride (such as AlF or the like) is removed by sputtering, thereby suppressing the formation of a conductive fluoride film.

During the substrate processing S101, the AC voltage Vₚₗₐₛₘₐ for measurement that is applied to the probe device 70 is, for example, an AC voltage with an amplitude of 1 V to 2 V (2 Vpp to 4 Vpp, 1 V to 2 V at 0-to-peak). Further, at voltages close thereto, the force that attracts electrons and ions is small, so that the adhered conductive fluoride (such as AlF or the like) cannot be removed.

Here, the voltage V_{clean} applied to the probe device 70 during the cleaning process S102 may be a positive (+) direct current (DC) voltage. In this case, the voltage range is preferably within the range of +5V to +30V. In this case, electrons are attracted to the surface of the probe device 70, and the adhered conductive fluoride (AlF or the like) is removed. Further, in the cleaning process S102, only a positive (+) DC voltage may be applied to the probe device 70, or a positive (+) DC voltage may be superimposed on a measurement AC voltage and applied to the probe device 70.

Further, the voltage V_{clean} applied to the probe device 70 in the cleaning process S102 may be a negative (−) DC voltage. In this case, the voltage range is preferably within the range of −10 V to −100 V. In this case, ions are attracted to the surface of the probe device 70, and the adhered conductive fluoride (AlF or the like) is removed. In addition, in the cleaning process S102, only a negative (−) DC voltage may be applied to the probe device 70, or a negative (−) DC voltage may be superimposed on the AC voltage for measurement and applied to the probe device 70.

In addition, the voltage V_{clean} applied to the probe device 70 in the cleaning process S102 may be an AC voltage. In this case, the amplitude range is preferably within a range of 5 V to 30 V. In this case, electrons and ions are attracted to the surface of the probe device 70, and the adhered conductive fluoride (AlF or the like) is removed. In addition, by using an AC voltage, electrons and ions can be attracted more desirably even when the insulating film 200 is formed on the surface of the probe device 70, compared to the case of using a DC voltage. Further, in the cleaning process S102, only an AC voltage may be applied to the probe device 70, or an AC voltage may be superimposed on the AC voltage for measurement and applied to the probe device 70.

The voltage V_{clean} applied to the probe device 70 in the cleaning process S102 may be a pulse voltage. In this case, the voltage range is preferably within the range of −10 V to −100 V in the case of a negative pulse voltage, and preferably within the range of +5 V to +30 V in the case of a positive pulse voltage. In this case, electrons and/or ions are attracted to the surface of the probe device 70, and the adhered conductive fluoride (AlF or the like) is removed. In addition, by using a pulse voltage, it is possible to attract electrons and/or ions more desirably even when the insulating film 200 is formed on the surface of the probe device 70, compared to the case of using a DC voltage. In addition, in the cleaning process S102, only a pulse voltage may be applied to the probe device 70, or a pulse voltage may be superimposed on an AC voltage for measurement and applied to the probe device 70. In addition, by controlling the duty ratio of the pulse voltage, the effect of removing conductive fluoride (AlF or the like) can be adjusted.

The cleaning gas may contain a rare gas such as Ar gas in addition to a gas containing fluorine (F) (e.g., NF₃ or the like). Accordingly, Ar ions can sputter and effectively remove conductive fluoride (AlF or the like) adhered to the surface of the probe device 70. Alternatively, a process of cleaning the probe with an inert gas (Ar, N₂, or the like) may be added after the cleaning using the cleaning gas.

Further, the surface of the probe device 70 may be covered with a coating material (e.g., SiO₂) to protect it from the processing gas and the cleaning gas. The ion energy based on the voltage V_{clean} applied to the probe device 70 in the cleaning process S102 is preferably smaller than the threshold ion energy of the coating material (e.g., 50 eV or less). Accordingly, it is possible to prevent the coating material (SiO₂) on the surface of the probe device 70 from being etched by the ions in the plasma. Further, the conductive fluoride (AlF or the like) that is adhered as by-products in the cleaning process S102 is deposited on the surface of the probe device 70, and thus has a small attractive force and can be removed with the ion energy lower than or equal to the threshold voltage of the coating material.

FIGS. 8A to 8C show examples of a circuit configuration for applying a voltage to the probe device 70.

In the example shown in FIG. 8A, the plasma measurement system includes the probe device 70, a blocking capacitor 72, and a signal generator 82. In this example, one AC power supply (the signal generator 82) serves both as a measurement power supply that applies an AC voltage Vₚₗₐₛₘₐ for plasma measurement to the probe device 70, and as a cleaning power supply that applies an AC voltage V_{clean} to the probe device 70 to attract electrons and ions during cleaning. In other words, the signal generator 82 is configured to be able to vary the amplitude of the AC voltage applied to the probe device 70, and makes the absolute value (amplitude) of the AC voltage V_{clean} applied to the probe device 70 during the cleaning greater than the absolute value (amplitude) of the AC voltage Vₚₗₐₛₘₐ applied to the probe device 70 during the plasma measurement.

In the example shown in FIG. 8B, the plasma measurement system includes the probe device 70, the blocking capacitor 72, the signal generator 82 (measurement power supply), a cleaning power supply 91, and a switch 92. The signal generator 82 (measurement power supply) and the cleaning power supply 91 are provided on the opposite side of the probe device 70 when viewed from the blocking capacitor 72. Further, the signal generator 82 (measurement power supply) and the cleaning power supply 91 are arranged in series. Further, the cleaning power supply 91 may be bypassed and disconnected from the circuit by switching the switch 92. The cleaning power supply 91 may be an AC power supply that supplies an AC voltage or a pulse power supply that supplies a pulse voltage. During the plasma measurement, the switch 92 is switched to the ground side, and the signal generator 82 applies an AC voltage Vₚₗₐₛₘₐ for plasma measurement to the probe device 70. During the cleaning, the switch 92 is switched to the cleaning power supply 91 side, and a voltage V_{clean} obtained by superimposing the voltage (AC voltage or pulse voltage) of the cleaning power supply 91 on the AC voltage of the signal generator 82 is applied to the probe device 70.

In the example shown in FIG. 8C, the plasma measurement system includes the probe device 70, the blocking capacitor 72, the signal generator 82 (measurement power supply), a cleaning power supply 93, and a switch 94. The signal generator 82 (measurement power supply) and the cleaning power supply 93 are provided on the opposite side of the probe device 70 when viewed from the blocking capacitor 72. Further, the signal generator 82 (measurement power supply) and the cleaning power supply 93 are arranged in parallel. Further, the switch 94 is configured to switch the power supply that supplies a voltage to the probe device 70. The cleaning power supply 93 may be an AC power supply that supplies an AC voltage, or a pulse power supply that supplies a pulse voltage. During the plasma measurement, the switch 94 is switched to the signal generator 82 (measurement power supply) side, and the signal generator 82 applies an AC voltage Vₚₗₐₛₘₐ for plasma measurement to the probe device 70. During the cleaning, the switch 94 is switched to the cleaning power supply 93 side, and the voltage (AC voltage or pulse voltage) V_{clean} of the cleaning power supply 91 is applied to the probe device 70.

FIG. 9 is another example of a diagram showing a circuit configuration for applying a voltage to the probe device 70.

In the example shown in FIG. 9, the plasma measurement system includes the probe device 70, the blocking capacitor 72, the signal generator 82 (measurement power supply), and a cleaning power supply 95. The signal generator 82 (measurement power supply) is provided on the opposite side of the probe device 70 when viewed from the blocking capacitor 72, and the cleaning power supply 95 is provided on the same side as the probe device 70 when viewed from the blocking capacitor 72. Further, the signal generator 82 (measurement power supply) and the cleaning power supply 95 are arranged in parallel. The cleaning power supply 95 may be a DC power supply that supplies a positive or negative DC voltage, an AC power supply that supplies an AC voltage, or a pulse power supply that supplies a pulse voltage. During the plasma measurement, the signal generator 82 applies an AC voltage Vₚₗₐₛₘₐ for plasma measurement to the probe device 70. During the cleaning, the voltage V_{clean} of the cleaning power supply 95 (any one of a positive or negative DC voltage, an AC voltage, and a pulse voltage) is applied to the probe device 70. Further, during the cleaning, a voltage V_{clean} obtained by superimposing the voltage (any one of a positive or negative DC voltage, an AC voltage, or a pulse voltage) of the cleaning power supply 95 on the AC voltage of the signal generator 82 may be applied to the probe device 70.

In addition, in the configuration shown in FIG. 9, a voltage can be applied directly to the probe device 70 without passing through the blocking capacitor 72, so that a DC power supply that supplies a positive or negative DC voltage can be used as the cleaning power supply 95.

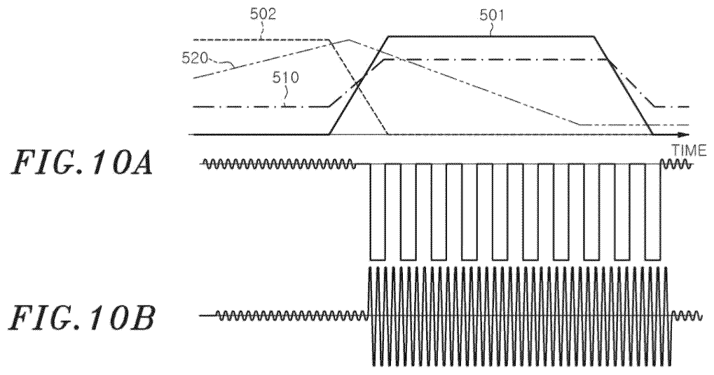

An example of the voltage applied to the probe device 70 will be described with reference to FIGS. 10A and 10B. FIGS. 10A and 10B are diagrams showing an example of the voltage applied to the probe device 70.

FIG. 10A shows an example of the configuration of FIG. 8C (or the configuration of FIG. 9) in which the cleaning power supply 93 (or the cleaning power supply 95) is a pulse power supply that supplies a negative pulse voltage. As shown in FIG. 10A, during the plasma measurement, the signal generator 82 applies the AC voltage Vₚₗₐₛₘₐ for plasma measurement to the probe device 70. During the cleaning, the cleaning power supply 93 (or the cleaning power supply 95) applies a negative pulse voltage V_{clean} to the probe device 70. The absolute value of the pulse voltage V_{clean} for cleaning is greater than the absolute value (amplitude) of the AC voltage Vₚₗₐₛₘₐ for plasma measurement.

FIG. 10B shows an example of the configuration of FIG. 8A (or the configuration of FIG. 9) in which the cleaning power supply (the signal generator 82 or the cleaning power supply 95 that also serves as a cleaning power supply) is an AC power supply. As shown in FIG. 10B, during the plasma measurement, the signal generator 82 applies the AC voltage Vₚₗₐₛₘₐ for plasma measurement to the probe device 70. During the cleaning, the AC voltage V_{clean} is applied to the probe device 70 from the cleaning power supply (the signal generator 82 or the cleaning power supply 95 that also serves as the cleaning power supply). The absolute value (amplitude) of the AC voltage V_{clean} during the cleaning is greater than the absolute value (amplitude) of the AC voltage Vₚₗₐₛₘₐ during the plasma measurement.

In addition, in the configuration shown in FIG. 10B, as a secondary effect, the AC voltage for plasma measurement applied to the probe device 70 during the cleaning is increased. In the conventional measurement method, the signal is relatively small during the cleaning (the plasma electron density is relatively small), which makes it difficult to estimate the plasma state. Hence, by increasing the AC voltage for plasma measurement, the plasma state can be estimated even during the cleaning. Further, by estimating the plasma state during the cleaning, it is possible to detect the end point of the cleaning.

In the first substrate processing method shown in FIG. 7, a cleaning voltage greater than the AC voltage Vₚₗₐₛₘₐ for plasma measurement is applied to the probe device 70 during the cleaning process S102. However, the present disclosure is not limited thereto.

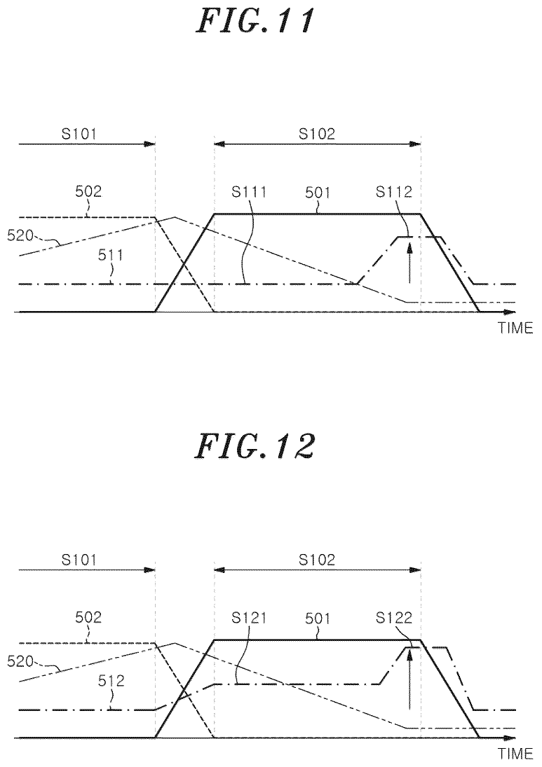

FIG. 11 is an example of a diagram schematically showing the supply of a processing gas, the supply of a cleaning gas, a voltage supplied to the probe device 70, and changes in a film thickness in a second substrate processing method. Here, the processing gas supply 502 in step S101 is indicated by a dashed line, the cleaning gas supply 501 used in step S102 is indicated by a solid line, a voltage 511 supplied to the probe device 70 is indicated by a dashed dotted line, and the film thickness 520 of the insulating film 200 of the probe device 70 is indicated by a dashed double-dotted line. Further, the second substrate processing method shown in FIG. 11 can be applied to, for example, the circuit configuration shown in FIG. 9. Further, a positive or negative DC power supply can be used as the cleaning power supply 95.

Step S102 includes a process S111 of applying a first voltage to the probe device 70, and a process S112 of applying a second voltage to the probe device 70.

Subsequent to step S101, in the process S111, an AC voltage for plasma measurement (first voltage) is applied to the probe device 70. Further, the case in which the first voltage is applied is not limited to the case in which the AC voltage for plasma measurement is applied, and also includes the case in which the AC voltage for plasma measurement is not applied. In the process S111, the insulating film 200 deposited on the probe device 70 is removed by the plasma of the cleaning gas.

In the process S112, a positive or negative DC voltage (second voltage) is applied to the probe device 70. Here, the second voltage is a DC voltage having an absolute value greater than the absolute value of the first voltage and greater than the absolute value of the AC voltage for plasma measurement. By applying a DC voltage for cleaning after the removal of the insulating film 200, it is possible to desirably remove conductive fluoride. In particular, by applying a positive DC voltage to the probe device 70, it is possible to efficiently remove conductive fluoride.

FIG. 12 is an example of a diagram schematically showing the supply of a processing gas, the supply of a cleaning gas, a voltage supplied to the probe device 70, and changes in a film thickness in a third substrate processing method. Here, the processing gas supply 502 used in step S101 is indicated by a dashed line, the cleaning gas supply 501 used in step S102 is indicated by a solid line, a voltage 512 supplied to the probe device 70 is indicated by a dashed dotted line, and the film thickness 520 of the insulating film 200 of the probe device 70 is indicated by a dashed double-dotted line. Further, the third substrate processing method shown in FIG. 12 can be applied to a circuit configuration including a cleaning power supply (the cleaning power supply 91 in FIG. 8B, the cleaning power supply 93 in FIG. 8C, and the cleaning power supply 95 in FIG. 9 when the signal generator 82 in FIG. 8A serves as the cleaning power supply) that applies an AC voltage or a pulse voltage (first voltage) to the probe device 70, and a cleaning power supply (the cleaning power supply 95 in FIG. 9) that applies a positive or negative DC voltage to the probe device 70.

Step S102 includes a process S121 of applying a first voltage to the probe device 70 and a process S122 of applying a second voltage to the probe device 70.

In the process S121, an AC voltage or a pulse voltage (first voltage) is applied to the probe device 70. By using an AC voltage or a pulse voltage, it is possible to remove conductive fluoride even when the insulating film 200 is deposited on the probe device 70. Further, in the process S121, the insulating film 200 deposited on the probe device 70 is removed by plasma of the cleaning gas.

In the process S122, a positive or negative DC voltage (second voltage) is applied to the probe device 70. Here, the second voltage is a DC voltage having an absolute value greater than the absolute value of the first voltage and greater than the absolute value of the AC voltage for plasma measurement. By applying a DC voltage for cleaning after the removal of the insulating film 200, it is possible to desirably remove conductive fluoride. In particular, by applying a positive DC voltage to the probe device 70, it is possible to efficiently remove conductive fluoride.

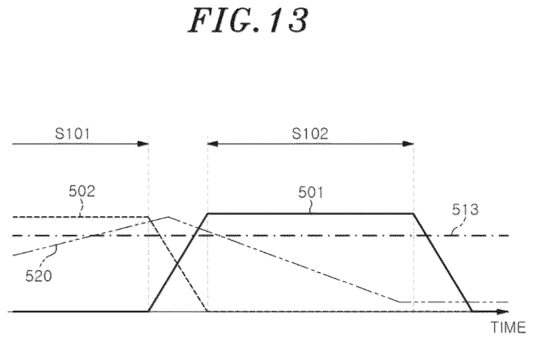

FIG. 13 is an example of a diagram schematically showing the supply of a processing gas, the supply of a cleaning gas, a voltage supplied to the probe device 70, and changes in a film thickness in a fourth substrate processing method. Here, the process gas supply 502 used in step S101 is indicated by a dashed line, the cleaning gas supply 501 used in step S102 is indicated by a solid line, a voltage 513 supplied to the probe device 70 is indicated by a dashed dotted line, and the film thickness 520 of the insulating film 200 of the probe device 70 is indicated by a dashed double-dotted line.

Here, a voltage obtained by superimposing a DC voltage for cleaning on the AC voltage for plasma measurement is applied to the probe device 70 not only during step S102 but also during step S101.

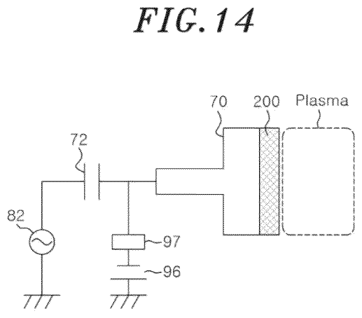

FIG. 14 is still another example of a diagram showing a circuit configuration for applying a voltage to the probe device 70.

In the example shown in FIG. 14, the plasma measurement system includes the probe device 70, the blocking capacitor 72, the signal generator 82 (measurement power supply), a cleaning DC power supply 96, and a filter 97. The signal generator 82 (measurement power supply) is provided on the opposite side of the probe device 70 when viewed from the blocking capacitor 72, and the cleaning DC power supply 96 is provided on the same side of the probe device 70 when viewed from the blocking capacitor 72. The cleaning DC power supply 96 is connected to the probe device 70 via the filter 97 that cuts an AC voltage. Further, the signal generator 82 (measurement power supply) and the cleaning DC power supply 96 are arranged in parallel. The cleaning DC power supply 96 is a DC power supply that supplies a positive or negative DC voltage.

With this configuration, the control can be simplified.

As described above, in accordance with the substrate processing method of the present embodiment, it is possible to prevent a decrease in the estimation accuracy of the plasma state due to the adhesion of fluoride, which has finite conductivity, to the probe device 70 during the cleaning. In other words, it is possible to improve the estimation accuracy of the plasma by the plasma measurement system.

Although the case in which fluoride having finite conductivity is adhered to the probe device 70 has been described as an example, the present disclosure is not limited thereto, and can also be applied to surface oxides, nitrides, or the like having finite conductivity.

While the plasma processing apparatus 100 has been described above, the present disclosure is not limited to the above-described embodiments, and various changes and modifications can be made without departing from the scope of the appended claims and the gist thereof.

1. A method for controlling a plasma measurement system including a probe device of a plasma processing apparatus, and a measurement circuit that outputs an AC voltage for plasma measurement to the probe device and measures a state of plasma generated by the plasma processing apparatus,
wherein an absolute value of a voltage applied to the probe device during cleaning of the plasma processing apparatus is greater than an absolute value of the AC voltage for the plasma measurement.

2. The method for controlling a plasma measurement system of claim 1, comprising:
applying a first voltage to the probe device and then applying a second voltage to the probe device during the cleaning of the plasma processing apparatus,
wherein the second voltage is a DC voltage having an absolute value greater than an absolute value of the first voltage and greater than the absolute value of the AC voltage for the plasma measurement.

3. The method for controlling a plasma measurement system of claim 2, wherein the first voltage is the same as the AC voltage for the plasma measurement, or the AC voltage for plasma measurement is not applied.

4. The method for controlling a plasma measurement system of claim 2, wherein the first voltage is an AC voltage or a pulse voltage.

5. The method for controlling a plasma measurement system of claim 1, wherein the voltage applied to the probe device during the cleaning of the plasma processing apparatus is a voltage that ensures ion energy attracted to the probe device is less than threshold ion energy of a probe surface coating material covering the probe device.

6. The method for controlling a plasma measurement system of claim 1, wherein plasma of a cleaning gas containing fluorine is generated in a processing chamber of the plasma processing apparatus during the cleaning of the plasma processing apparatus.

7. A plasma measurement system comprising:
a probe device;
a measurement power supply for plasma measurement;
a blocking capacitor connected between the probe device and the measurement power supply; and
a cleaning power supply connected between the blocking capacitor and the probe device and connected in parallel to the measurement power supply.

8. The plasma measurement system of claim 7, wherein the cleaning power supply outputs a DC voltage having an absolute value greater than an absolute value of a voltage for the plasma measurement output from the measurement power supply.

9. The plasma measurement system of claim 7, wherein the cleaning power supply outputs an AC voltage having an absolute value greater than an absolute value of a voltage for the plasma measurement output from the measurement power supply.

10. The plasma measurement system of claim 7, wherein the cleaning power supply outputs a pulse voltage having an absolute value greater than an absolute value of a voltage for the plasma measurement output from the measurement power supply.

11. A plasma measurement system comprising:
a probe device;
a measurement power supply for plasma measurement;
a blocking capacitor connected between the probe device and the measurement power supply; and
a cleaning power supply provided on the opposite side of the probe device when viewed from the blocking capacitor.

12. The plasma measurement system of claim 11, wherein the cleaning power supply is connected in series to the measurement power supply.

13. The plasma measurement system of claim 11, wherein the cleaning power supply is connected in parallel to the measurement power supply.

14. The plasma measurement system of claim 11, wherein the cleaning power supply outputs an AC voltage having an absolute value greater than an absolute value of a voltage for the plasma measurement output from the measurement power supply.

15. The plasma measurement system of claim 11, wherein the cleaning power supply outputs a pulse voltage having an absolute value greater than an absolute value of a voltage for the plasma measurement output from the measurement power supply.
